(19) United States
(12) Patent Application Publication
(10) Pub. No.: US 2022/0025171 A1
(43) Pub. Date: Jan. 27, 2022

(54) RESIN COMPOSITION, PREPREG, FILM WITH RESIN, METAL FOIL WITH RESIN, METAL-CLAD LAMINATE, AND PRINTED WIRING BOARD

(71) Applicant: PANASONIC INTELLECTUAL PROPERTY MANAGEMENT CO., LTD., Osaka (JP)

(72) Inventors: Tomo MUGURUMA, Fukushima (JP); Ryuji TAKAHASHI, Fukushima (JP); Shimpei OBATA, Osaka (JP); Yasunori AMBE, Fukushima (JP)

(21) Appl. No.: 17/311,542

(22) PCT Filed: Nov. 15, 2019
(86) PCT No.: PCT/JP2019/044794

§ 371 Date: Jun. 7, 2021

(30) Foreign Application Priority Data
Dec. 12, 2018 (JP) 2018-232828

(51) Int. Cl. C08L 63/00; C08J 5/24; C08J 5/18; H05K 1/03

(52) U.S. Cl. CPC C08L 63/00; C08J 5/249; C08J 5/18; H05K 1/0373; C08L 2207/53; C08L 2205/035; C08J 2425/12; C08L 2203/202; C08J 2363/00; C08J 2445/00; C08J 2433/12; C08J 2453/02; C08J 2483/04; C08L 2203/16

(57) ABSTRACT

A resin composition contains an epoxy compound, a maleimide compound, a phenolic compound, core-shell rubber, and an inorganic filler. The maleimide compound has an N-phenyl maleimide structure. The content of the maleimide compound falls within a range from 10 parts by mass to less than 40 parts by mass with respect to 100 parts by mass in total of the epoxy compound, the maleimide compound, and the phenolic compound.

### TECHNICAL FIELD

The present disclosure generally relates to a resin composition, a prepreg, a film with resin, a sheet of metal foil with resin, a metal-clad laminate, and a printed wiring board. More particularly, the present disclosure relates to a resin composition containing an epoxy compound, a prepreg, a film with resin, a sheet of metal foil with resin, a metal-clad laminate, and a printed wiring board.

### BACKGROUND ART

Printed wiring boards are widely used in a broad variety of fields including electronic equipment, communications devices, and computers. Recently, small-sized mobile electronic devices such as mobile telecommunications devices and laptop personal computers (PCs), among other things, have had their functionality improved, their performance enhanced, and their thickness and dimensions reduced significantly and rapidly. To catch up with these trends, as for printed wiring boards for use in these products, there have been increasing demands for even reducing the feature size of their conductor wiring, implementing their conductor wiring layer in multiple levels at a reduced thickness, and further improving their performance in terms of their mechanical properties, for example. Among other things, as the thickness of printed wiring boards has been reduced, a semiconductor package (semiconductor device), formed by mounting a semiconductor chip on a printed wiring board, is more and more likely to be warped, thus increasing the chances of causing mounting failures.

Patent Literature 1 discloses a semiconductor device formed by mounting a semiconductor element on a printed wiring board. The printed wiring board is obtained by subjecting a metal-clad laminate to a circuit forming process. The metal-clad laminate has two sheets of metal foil, which are respectively provided on both surfaces of an insulating layer including an epoxy resin composition and a fiber base member. The epoxy resin composition contains an epoxy resin, a bismaleimide compound, and an inorganic filler. Also, the degree of hysteresis of a dimensional variation of the metal-clad laminate within the range of 30° C. to 260° C. falls within a predetermined range. In this manner, according to Patent Literature 1, the warpage of the metal-clad laminate is reduced.

However, the metal-clad laminate of Patent Literature 1 cannot sufficiently reduce the warpage of the semiconductor packages.

Thus, to reduce the warpage of semiconductor packages, the present inventors paid special attention to the coefficient of thermal expansion and glass transition temperature (Tg) of printed wiring boards.

Furthermore, to interconnect a plurality of conductor wiring patterns on two or more different layers of a printed wiring board, holes are opened through the printed wiring board either by drilling or laser cutting. When these holes are opened, resin smears are left on the inner walls of those holes. Thus, a desmear process needs to be performed to remove those resin smears. The desmear process is performed using a permanganate such as potassium permanganate.

However, if the resin smears were removed excessively by the desmear process (i.e., if the desmear etch rate were excessive), then the holes would be deformed and copper foil would be peeled off, for example, thus possibly causing a significant decline in the reliability of electrical conductivity of the printed wiring board. Thus, there has been an increasing demand for decreasing the desmear etch rate, i.e., improving the desmear resistance.

### CITATION LIST

### Patent Literature

Patent Literature 1: JP 2015-063040 A

### SUMMARY OF INVENTION

It is therefore an object of the present disclosure to provide a resin composition, a prepreg, a film with resin, a sheet of metal foil with resin, a metal-clad laminate, and a printed wiring board, all of which contribute to obtaining a board having a low coefficient of thermal expansion, a high glass transition temperature (Tg), and excellent desmear resistance.

A resin composition according to an aspect of the present disclosure contains an epoxy compound, a phenolic compound, a maleimide compound, core-shell rubber, and an inorganic filler. The maleimide compound has an N-phenyl maleimide structure. The content of the maleimide compound falls within a range from 10 parts by mass to less than 40 parts by mass with respect to 100 parts by mass in total of the epoxy compound, the maleimide compound, and the phenolic compound.

A prepreg according to another aspect of the present disclosure includes: a base member: and a resin layer made of a semi-cured product of the resin composition impregnated into the base member.

A film with resin according to still another aspect of the present disclosure includes: a resin layer made of a semi-cured product of the resin composition; and a supporting film supporting the resin layer thereon.

A sheet of metal foil with resin according to yet another aspect of the present disclosure includes: a resin layer made of a semi-cured product of the resin composition; and a sheet of metal foil to which the resin layer is bonded.

A metal-clad laminate according to yet another aspect of the present disclosure includes: an insulating layer made of either a cured product of the resin composition or a cured product of the prepreg; and at least one metal layer formed on one surface or both surfaces of the insulating layer.

A printed wiring board according to yet another aspect of the present disclosure includes: an insulating layer made of either a cured product of the resin composition or a cured product of the prepreg; and at least one conductor wiring formed on one surface or both surfaces of the insulating layer.

### BRIEF DESCRIPTION OF DRAWINGS

FIG. 1 is a schematic cross-sectional view of a prepreg according to an exemplary embodiment of the present disclosure;

FIG. 2A is a schematic cross-sectional view of a film with resin (and with no protective film) according to the exemplary embodiment of the present disclosure;

FIG. 2B is a schematic cross-sectional view of a film with resin (and with a protective film) according to the exemplary embodiment of the present disclosure;

FIG. 3 is a schematic cross-sectional view of a sheet of metal foil with resin according to the exemplary embodiment of the present disclosure;

FIG. 4 is a schematic cross-sectional view of a metal-clad laminate according to the exemplary embodiment of the present disclosure; and

FIG. 5 is a schematic cross-sectional view of a printed wiring board according to the exemplary embodiment of the present disclosure.

### DESCRIPTION OF EMBODIMENTS

(1) Overview

A resin composition according to an exemplary embodiment contains an epoxy compound, a phenolic compound, a maleimide compound, core-shell rubber, and an inorganic filler. The maleimide compound has an N-phenyl maleimide structure. The content of the maleimide compound falls within a range from 10 parts by mass to less than 40 parts by mass with respect to 100 parts by mass in total of the epoxy compound, the maleimide compound, and the phenolic compound.

When the resin composition contains a particular content of a particular maleimide compound as described above, a board having a high glass transition temperature (Tg) and excellent desmear resistance may be obtained. When the glass transition temperature (Tg) is high, the thermal resistance is improvable. Also, when the desmear resistance is excellent, the change in via diameter before and after the desmear process is reducible. This allows the via diameter to be further decreased and also allows sufficient electrical insulation properties to be ensured even when a plurality of vias are arranged densely. Consequently, conductor wiring may be formed more finely.

In addition, when the resin composition includes core-shell rubber and an inorganic filler, a board with a low coefficient of thermal expansion may be obtained.

That is to say, this embodiment allows a board with a low coefficient of thermal expansion, a high glass transition temperature (Tg), and excellent desmear resistance to be obtained. Therefore, using a board obtained in this manner as a package board would contribute effectively to reducing the warpage of a semiconductor package.

(2) Details

(2.1) Resin Composition

A resin composition according to this embodiment may be used as a board material. Specific examples of board materials include prepregs, films with resin, sheets of metal foil with resin, metal-clad laminates, and printed wiring boards. However, these are only examples and should not be construed as limiting.

The resin composition contains an epoxy compound, a phenolic compound, a maleimide compound, core-shell rubber, and an inorganic filler. Thus, the resin composition may have thermosetting properties. The resin composition may further contain a curing accelerator. Optionally, the resin composition may further contain an additive.

The resin composition may be prepared, for example, in the following manner. Specifically, the epoxy compound, the phenolic compound, the maleimide compound, the core-shell rubber, and the inorganic filler are compounded together. The compound thus obtained is diluted with an appropriate solvent, and then the mixture is stirred up to have a uniform concentration.

Next, respective constituent components of the resin composition will be described.

(2.1.1) Epoxy Compound

The epoxy compound is a prepolymer and is a compound having at least two epoxy groups per molecule. Generally speaking, the term “resin” refers to two different types of resins, namely, a resin as a material yet to be cross-linked (such as an epoxy compound) and a resin as a cross-linked product (final product). As used herein, the “resin” basically refers to the former type of a resin.

Specific examples of the epoxy compound include bisphenol type epoxy resins, novolac type epoxy resins, biphenyl type epoxy resins, xylylene type epoxy resins, aryl alkylene type epoxy resins, naphthalene type epoxy resins, naphthalene skeleton modified epoxy resins, triphenylmethane type epoxy resins, anthracene-type epoxy resins, dicyclopentadiene-type epoxy resins, norbornene type epoxy resins, fluorene type epoxy resins, and flame-retardant epoxy resins obtained by halogenating any of these epoxy resins. However, these are only examples and should not be construed as limiting. The resin composition may contain only one type of epoxy compound or two or more types of epoxy compounds, whichever is appropriate.

Specific examples of the bisphenol type epoxy resins include bisphenol A type epoxy resins, bisphenol F type epoxy resins, and bisphenol S type epoxy resins. However, these are only examples and should not be construed as limiting.

Specific examples of the novolac type epoxy resins include phenol novolac type epoxy resins and cresol novolac type epoxy resins. However, these are only examples and should not be construed as limiting.

Specific examples of the aryl alkylene type epoxy resins include phenol aralkyl type epoxy resins, biphenyl aralkyl type epoxy resins, biphenyl novolac type epoxy resins, biphenyl dimethylene type epoxy resins, trisphenol methane novolac type epoxy resins, and tetramethyl biphenyl type epoxy resins. However, these are only examples and should not be construed as limiting.

Specific examples of the naphthalene skeleton-modified epoxy resins include naphthalene skeleton-modified cresol novolac type epoxy resins, naphthalene diol aralkyl type epoxy resins, naphthol aralkyl type epoxy resins, methoxy naphthalene modified cresol novolac type epoxy resins, and methoxy naphthalene dimethylene type epoxy resins. However, these are only examples and should not be construed as limiting.

The epoxy compound suitably includes an epoxy compound having at least one of a naphthalene skeleton or a biphenyl skeleton.

An epoxy compound having the naphthalene skeleton may have excellent thermal resistance, moisture resistance, and flame retardance. This allows a resin composition exhibiting excellent properties in these respects to be obtained. As used herein, the phrase “excellent in heat resistance” means that the glass transition temperature (Tg) is high.

An epoxy compound having the biphenyl skeleton may have crystalline properties at a normal temperature. Such an epoxy compound is a solid resin but may have as low viscosity as a liquid resin's when melted. Thus, even if the resin composition is filled with an inorganic filler at a high percentage, the resin composition may still maintain excellent flowability when melted.

Furthermore, the epoxy compound having the biphenyl skeleton may have excellent flame retardance, thermal resistance, and adhesiveness. This allows a resin composition exhibiting excellent properties in these respects to be obtained.

The epoxy equivalent of the epoxy compound suitably falls within the range of 150 g/eq to 350 g/eq.

(2.1.2) Phenolic Compound

The phenolic compound is a prepolymer that may react to the epoxy compound. The phenolic compound is a product of condensation reaction between a phenol and an aldehyde.

Specific examples of the phenolic compound include biphenyl aralkyl type phenolic resins, phenyl aralkyl type phenolic resins, novolac-type phenolic resins, cresol novolac type phenolic resins, bisphenol A novolac type phenolic resins, naphthalene type phenolic resins, tetrakisphenol type phenolic resins, and phosphorus modified phenolic resins. However, these are only examples and should not be construed as limiting. The resin composition may contain only one type of phenolic compound or two or more types of phenolic compounds, whichever is appropriate.

The phenolic compound suitably includes a phenolic compound having at least one of a naphthalene skeleton or a biphenyl skeleton.

A phenolic compound having the naphthalene skeleton may have the same properties as the epoxy compound having the naphthalene skeleton. Thus, a resin composition with excellent thermal resistance, moisture resistance, and flame retardance may be obtained.

A phenolic compound having the biphenyl skeleton may have the same properties as the epoxy compound having the biphenyl skeleton. Thus, even if the resin composition is filled with an inorganic filler at a high percentage, the resin composition may still maintain excellent flowability when melted.

Furthermore, the phenolic compound having the biphenyl skeleton may have excellent flame retardance, thermal resistance, and adhesiveness. This allows a resin composition exhibiting excellent properties in these respects to be obtained.

The phenolic compound is suitably a phosphorus-containing phenolic compound. The phosphorus-containing phenolic compound contains phosphorus and may function as a flame retardant. Specifically, when exposed to flames, phosphorus is sequentially decomposed into phosphoric acid, metaphosphoric acid, and polymetaphosphoric acid, and a phosphoric acid layer thus produced may form a nonvolatile protective layer to shut off the air. Furthermore, the polymetaphosphoric acid thus generated carbonizes organic substances by strong dehydrating action, and a carbonized film thus formed may shut off the air. Thus, a resin composition having excellent flame retardance may be obtained.

In general, flame retardants may be classified into addition types and reaction types. The phosphorus-containing phenolic compound is not an addition type but a reaction type. That is to say, the phosphorus-containing phenolic compound has a functional group such as a hydroxy group and is chemically bonded to the epoxy compound by chemical reaction. Therefore, not only flame retardance but also desmear resistance may be imparted to the resin composition. An addition-type flame retardant may cause a decline in desmear resistance, and therefore, should not be contained in the resin composition.

The phosphorus-containing phenolic compound suitably has, in its molecule, a structure expressed by the following Chemical Formula (4), even though this is only an example and should not be construed as limiting. Furthermore, the phosphorus-containing phenolic compound suitably has, in its molecule, a bisphenol A type structure. Such a phosphorus-containing phenolic compound having the structure expressed by the following Chemical Formula (4) and the bisphenol A type structure may be, for example, “XZ92741.00” manufactured by the Dow Chemical Company Japan.

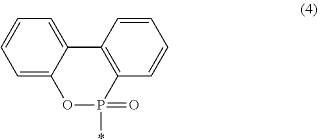 [SMILES: *P1(=O)Oc2ccccc2-c2ccccc21]

where * indicates a bond.

The content of the phenolic compound suitably falls within the range from 10 parts by mass to 30 parts by mass with respect to 100 parts by mass in total of the epoxy compound, the maleimide compound, and the phenolic compound. Setting the content of the phenolic compound at 10 parts by mass or more reduces the chances of causing a decline in glass transition temperature (Tg) or sufficient curing. This reduces the percentage of the unreacted resin, thus curbing a decline in the desmear resistance. Meanwhile, setting the content of the phenolic compound at 30 parts by mass or less reduces an increase in polar groups such as a hydroxyl group and curbs a decline in the desmear resistance.

The resin composition may contain both a phosphorus-containing phenolic compound and a phenolic compound containing no phosphorus. If the resin composition contains both of these compounds, then the mass ratio of the (phosphorus-containing phenolic compound/phenolic compound containing no phosphorus) suitably falls within the range from 15/100 to 50/100.

(2.1.3) Maleimide Compound Having N-Phenyl Maleimide Structure

The maleimide compound having the N-phenyl maleimide structure is a compound which may react to the epoxy compound and the phenolic compound. The maleimide compound having the N-phenyl maleimide structure has at least one N-phenyl maleimide structure. In the following description, the “maleimide compound having the N-phenyl maleimide structure” will be hereinafter simply referred to as a “maleimide compound” unless otherwise stated. The N-phenyl maleimide structure is expressed by the following Chemical Formula (3). The maleimide compound effectively contributes to increasing Tg of a cured product of the resin composition.

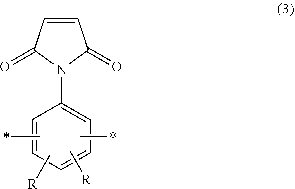

where R represents groups which are either the same as, or different from, each other, and each of which is either a hydrogen atom or an alkyl group; and * represents bonds, of which the number may be only one.

Note that the number of carbon atoms in the alkyl group represented by R in Formula (3) is not limited to any particular number. The alkyl group may have a straight chain or a branched chain, whichever is appropriate. Specific examples of the alkyl group represented by R include alkyl groups having one to three carbon atoms.

The maleimide compound suitably has at least one biphenyl structure. The maleimide compound having the biphenyl structure may have the same properties as the epoxy compound having the biphenyl skeleton. Thus, even if the resin composition is filled with an inorganic filler at a high percentage, the resin composition may still maintain excellent flowability when melted. In addition, a resin composition with excellent flame retardance and other beneficial properties may be obtained.

The maleimide compound suitably includes a compound expressed by the following Chemical Formula (1). This maleimide compound has a biphenyl skeleton. Thus, even if the resin composition is filled with an inorganic filler at a high percentage, the resin composition may still maintain excellent flowability when melted. In addition, a resin composition with excellent flame retardance and other beneficial properties may be obtained.

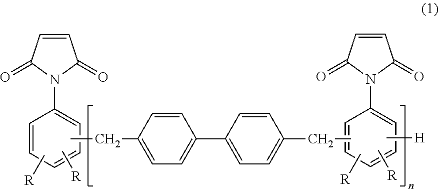

where R represents groups which are either the same as, or different from, each other, and each of which is either a hydrogen atom or an alkyl group; and n is an integer falling within a range from 0 to 4.

Note that the number of carbon atoms in the alkyl group represented by R in Formula (3) is not limited to any particular number. The alkyl group may have a straight chain or a branched chain, whichever is appropriate. Specific examples of the alkyl group represented by R include alkyl groups having one to three carbon atoms.

The maleimide compound includes a compound expressed by the following Chemical Formula (2). The maleimide compound allows a cured product of the resin composition to have a high Tg, thus improving the thermal resistance. In addition, the maleimide compound may also increase the modulus of elasticity of the cured product of the resin composition.

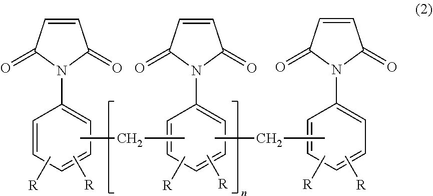

where R represents groups which are either the same as, or different from, each other, and each of which is either a hydrogen atom or an alkyl group; and n is an integer falling within a range from 0 to 4.

Note that the number of carbon atoms in the alkyl group represented by R in Chemical Formula (2) is not limited to any particular number. The alkyl group may have a straight chain or a branched chain, whichever is appropriate. Specific examples of the alkyl group represented by R include alkyl groups having one to two carbon atoms.

The resin composition may contain only one type of maleimide compound having the N-phenyl maleimide structure or two or more types of maleimide compounds each having the N-phenyl maleimide structure, whichever is appropriate. Specific examples of the maleimide compound include phenyl methane maleimide, 4,4′-diphenyl methane bismaleimide, m-phenylene bismaleimide, bisphenol A diphenyl ether bismaleimide, 3,3′-dimethyl-5,5′-diethyl-4,4′-diphenyl methane bismaleimide, and 4-methyl-1,3-phenylene bismaleimide. However, these are only examples and should not be construed as limiting. Further, the maleimide compound may be partially amine-modified and/or silicone-modified in its molecule.

The content of the maleimide compound having the N-phenyl maleimide structure falls within the range from 10 parts by mass to less than 40 parts by mass with respect to 100 parts by mass in total of the epoxy compound, the maleimide compound, and the phenolic compound. If the content of the maleimide compound were less than 10 parts by mass, then the glass transition temperature (Tg) could decrease. On the other hand, if the content of the maleimide compound were equal to or greater than 40 parts by mass, then the desmear resistance could decline.

(2.1.4) Core-Shell Rubber

The core shell rubber may function as an impact modifier. The core-shell rubber may reduce the thermal expansion of the cured product of the resin composition in cooperation with the inorganic filler. The core-shell rubber includes a core and a shell. The core is rubber in shape of a particle. The shell is a graft layer and covers the core.

The core suitably includes one or more substances selected from the group consisting of a polymer of (meth)acrylic acid, a polymer of a (meth)acrylate ester, a polymer of an olefin compound, polybutadiene, and silicone. The shell suitably includes one or more substances selected from the group consisting of a styrene-acrylonitrile copolymer, a polymer of (meth)acrylic acid, polybutadiene, and silicone. Such core-shell rubber may impart thermal resistance and low-temperature shock resistance to a cured product of the resin composition. An example of such core-shell rubber may be silicone-acrylic composite rubber. In the silicone-acrylic composite rubber, the core is a silicone/acrylic polymer, and the shell is a styrene acrylonitrile copolymer. As used herein, “(meth)acrylic acid” refers to at least one of acrylic acid or methacrylic acid.

Specific examples of the core shell rubber include: products named “S-2001,” “S-2006,” “S-2501,” “S-2030,” “S-2100,” “S-2200,” “SRK200A,” “SX-006,” and “SX-005” manufactured by Mitsubishi Chemical Corporation; products named “AC3816,” “AC3816N,” “AC3832,” “AC4030,” “AC3364,” and “IM101” manufactured by Aica Kogyo Co., Ltd.; products named “MX-217,” “MX-153,” “MX-960,” “MR-01,” “M-511,” and “M-521” manufactured by Kaneka Corporation; products named “EXL-2655,” “TMS-2670J,” and “TMS-2670S” manufactured by the Dow Chemical Company Japan; and products named “R-200” and “R-170S” manufactured by Nisshin Chemical Co., Ltd. However, these are only examples and should not be construed as limiting.

The core-shell rubber suitably has a mean particle size less than 1 μm. Such core-shell rubber is preferred for the following reason. Specifically, an insulating layer of a resin composition is sometimes formed over a surface having conductor wiring of a printed wiring board. In such a situation, if such core-shell rubber having a small mean particle size is contained in the resin composition, then the gap between adjacent parts of the conductor wiring may be filled more easily. This is particularly effectively applicable to a situation where fine-line conductor pattern (i.e., a so-called “fine pattern”) is densely formed on a printed wiring board. The same statement applies to not only when the insulating layer is provided in the form of the resin composition but also when the insulating layer is provided in the form of a prepreg, a film with resin, or a sheet of metal foil with resin. The lower limit value of the mean particle size of the core-shell rubber is not limited to any particular value but may be 0.1 μm, for example. As used herein, the “mean particle size” refers to a particle size with an integral value of 50% in a particle size distribution obtained by laser diffraction and scattering method.

The content of the core-shell rubber suitably falls within the range from 10 parts by mass to 50 parts by mass, and more suitably falls within the range from 17.5 parts by mass to 40 parts by mass, with respect to 100 parts by mass in total of the epoxy compound, the maleimide compound, and the phenolic compound. Setting the content of the core-shell rubber at 10 parts by mass or more allows the coefficient of thermal expansion to be decreased. Setting the content of the core-shell rubber at 50 parts by mass or less reduces the chances of causing a decline in the desmear resistance, a decrease in the glass transition temperature (Tg), a decrease in the degree of adhesiveness with respect to the sheet of metal foil (e.g., copper foil, in particular), and a decline in the flame retardance.

(2.1.5) Inorganic Filler

The inorganic filler contributes to reducing the thermal expansion of a cured product of the resin composition in cooperation with the core-shell rubber.

Specific examples of the inorganic filler include silica such as fused silica and crystalline silica, talc, boehmite, magnesium hydroxide, aluminum hydroxide, magnesium hydroxide, aluminum silicate, magnesium silicate, clay, and mica. However, these are only examples and should not be construed as limiting. The resin composition may contain only one type of inorganic filler or two or more types of inorganic fillers, whichever is appropriate.

The inorganic filler suitably includes one or more types of compounds selected from the group consisting of silica, talc, boehmite, magnesium hydroxide, and aluminum hydroxide. These inorganic fillers particularly effectively contribute to reducing the thermal expansion of a cured product of the resin composition. Among other things, the resin composition suitably contains silica and magnesium hydroxide.

The mean particle size of the inorganic filler suitably falls within the range from 0.1 μm to 3.0 μm, and more suitably falls within the range from 0.5 μm to 1.5 μm.

The content of the inorganic filler suitably falls within the range from 25 parts by mass to 200 parts by mass, and more suitably falls within the range from 50 parts by mass to 150 parts by mass, with respect to 100 parts by mass in total of the epoxy compound, the phenolic compound, and the maleimide compound.

If the resin composition contains silica and magnesium hydroxide as the inorganic fillers, the ratio by mass of silica to magnesium hydroxide (silica/magnesium hydroxide) suitably falls within the range from 50/2.5 to 150/2.5.

(2.1.6) Curing Accelerator

Unless the advantages of this embodiment are impaired, the type and content of the curing accelerator to add are not limited to any particular ones. Specific examples of the curing accelerator include imidazole compounds such as 2-ethyl-4-methylimidazole, amine compounds, thiol compounds, and organic acid metal salts such as metal soaps. However, these are only examples and should not be construed as limiting.

(2.1.7) Additive

Unless the advantages of this embodiment are impaired, the type and content of the additive to use are not limited to any particular ones. Specific examples of the additives include a thermoplastic resin, a flame retardant, a colorant, and a coupling agent. However, these are only examples and should not be construed as limiting.

(2.2) Prepreg

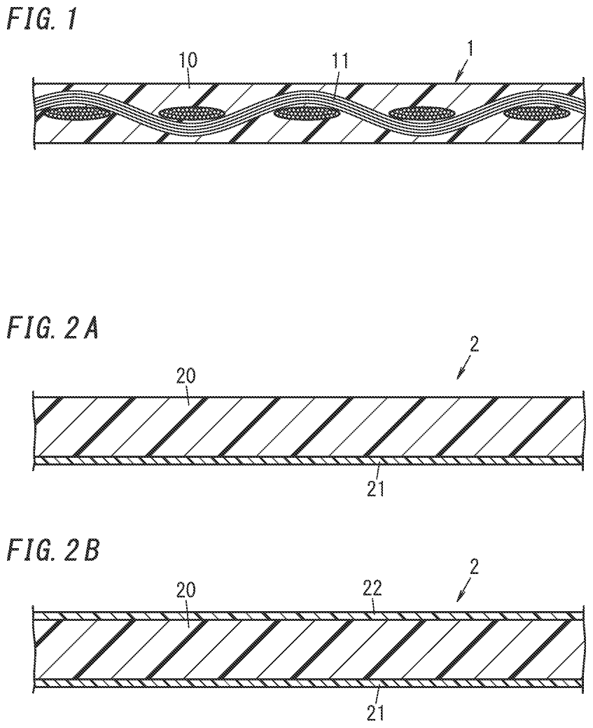

FIG. 1 illustrates a prepreg 1 according to this embodiment. The prepreg 1 has the shape of a sheet or a film as a whole. The prepreg 1 may be used as a material for the metal-clad laminate 4, as a material for the printed wiring board 5, and to form a printed wiring board 5 with multiple levels (by a buildup process).

The prepreg 1 includes a base member 11 and a resin layer 10. The resin layer 10 is made of a semi-cured product of the resin composition impregnated into the base member 11.

A single prepreg 1 includes at least one base member 11. The thickness of the base member 11 is not limited to any particular value but may fall within the range from 8 μm to 100 μm, for example. Specific examples of the base material 11 include woven fabric and non-woven fabric. Specifically, the woven fabric may be, but does not have to be, glass cloth. The non-woven fabric may be, but does not have to be, glass non-woven fabric. The glass cloth and the glass non-woven fabric are formed of glass fibers but may be formed of reinforcing fibers other than glass fibers. Any type of glass may be used without limitation to form the glass fibers. Specific examples of the glass include E glass, T glass, S glass, Q glass, UT glass, NE glass, and L glass. Specific examples of the reinforcing fibers include aromatic polyamide fiber, liquid crystal polyester fiber, poly(paraphenylene benzobisoxazole) (PBO) fiber, and polyphenylene sulfide (PPS) resin fiber. However, these are only examples and should not be construed as limiting.

The semi-cured product herein refers to the resin composition in a semi-cured state. As used herein, the “semi-cured state” refers to a state in an intermediate stage (Stage B) of the curing reaction. The intermediate stage is a stage between a varnish-state stage (Stage A) and a cured-state stage (Stage C). When heated, the prepreg 1 melts once. After that, the prepreg 1 is cured fully to turn into a cured product. The cured product of the prepreg 1 may constitute the insulating layer of the board.

The thickness of the prepreg 1 is not limited to any particular value but is suitably 120 μm or less, more suitably 100 μm or less, even more suitably 60 μm or less, and most suitably 40 μm or less. This allows the insulating layer to have a reduced thickness, thus reducing the overall thickness of the board as well. The prepreg 1 suitably has a thickness of 10 μm or more.

The resin layer 10 of the prepreg 1 is made of the resin composition according to this embodiment, thus allowing a board having a low coefficient of thermal expansion, a high glass transition temperature (Tg), and excellent desmear resistance to be obtained.

(2.3) Film with Resin

FIG. 2A illustrates a film with resin 2 according to this embodiment. The film with resin 2 has the shape of a film or sheet as a whole. The film with resin 2 includes a resin layer 20 and a supporting film 21. The film with resin 2 may be used to form a printed wiring board 5 with multiple levels (by a buildup process).

The resin layer 20 is formed of a semi-cured product of the resin composition. When heated, the semi-cured product may turn into a cured product. In this manner, the resin layer 20 may form an insulating layer.

The thickness of the resin layer 20 is not limited to any particular value but is suitably 120 μm or less, more suitably 100 μm or less, even more suitably 60 μm or less, and most suitably 40 μm or less. This allows the insulating layer to have a reduced thickness, thus reducing the overall thickness of the board as well. The resin layer 20 suitably has a thickness of 10 μm or more.

The supporting film 21 supports the resin layer 20 thereon. Supporting the resin layer 20 in this way allows the resin layer 20 to be handled more easily.

The supporting film 21 may be, but does not have to be, an electrically insulating film, for example. Specific examples of the supporting film 21 include a polyethylene terephthalate (PET) film, a polyimide film, a polyester film, a polyparabanic acid film, a polyether ether ketone film, a polyphenylene sulfide film, an aramid film, a polycarbonate film, and a polyarylate film. However, these are only examples and the supporting film 21 does not have to be one of these films.

A release agent layer (not shown) may be provided on the surface, used to support the resin layer 20, of the supporting film 21. The supporting film 21 may be peeled off from the resin layer 20 as needed by the release agent layer. After the resin layer 20 has been cured to form the insulating layer, the supporting film 21 is suitably peeled off from the insulating layer.

Although one surface of the resin layer 20 is covered with the supporting film 21 in the example shown in FIG. 2A, the other surface of the resin layer 20 may be protected with a protective film 22 as shown in FIG. 2B. Covering both surfaces of the resin layer 20 in this manner allows the resin layer 20 to be handled even more easily. This also reduces the chances of foreign particles adhering onto the resin layer 20.

The protective film 22 may be, but does not have to be, an electrically insulating film, for example. Specific examples of the protective film 22 include a polyethylene terephthalate (PET) film, a polyolefin film, a polyester film, and a polymethylpentene film. However, these are only examples and the protective film 22 does not have to be one of these films.

A release agent layer (not shown) may be provided on the surface, laid on top of the resin layer 20, of the protective film 22. The protective film 22 may be peeled off from the resin layer 20 as needed by the release agent layer.

The resin layer 20 of the film with resin 2 is formed of the resin composition according to this embodiment, thus allowing a board having a low coefficient of thermal expansion, a high glass transition temperature (Tg), and excellent desmear resistance to be obtained.

(2.4) Sheet of Metal Foil with Resin

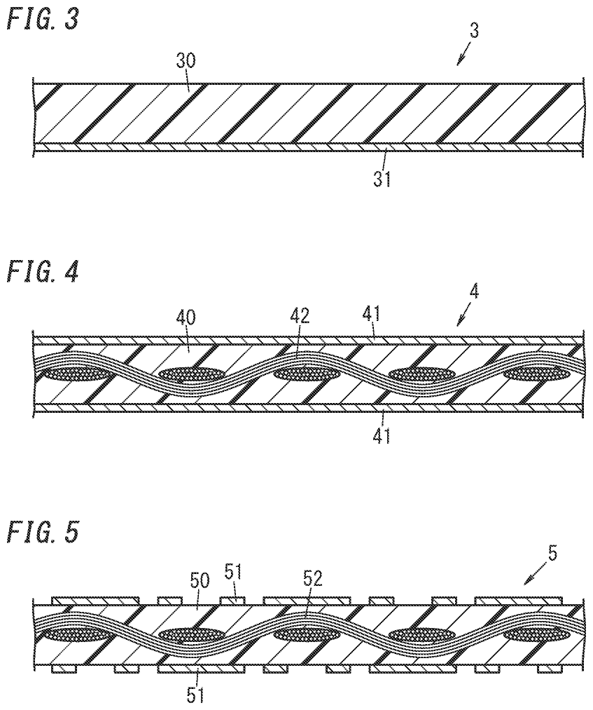

FIG. 3 illustrates a sheet of metal foil with resin 3 according to this embodiment. The sheet of metal foil with resin 3 has the shape of a film or sheet as a whole. The sheet of metal foil with resin 3 includes a resin layer 30 and a sheet of metal foil 31. The sheet of metal foil with resin 3 may be used to form a printed wiring board 5 with multiple levels (by a buildup process).

The resin layer 30 is formed of a semi-cured product of the resin composition. When heated, the semi-cured product may turn into a cured product. In this manner, the resin layer 30 may form an insulating layer.

The thickness of the resin layer 30 is not limited to any particular value but is suitably 120 μm or less, more suitably 100 μm or less, even more suitably 60 μm or less, and most suitably 40 μm or less. This allows the insulating layer, which is formed by curing the resin layer 30, to have a reduced thickness, thus reducing the overall thickness of the board as well. The resin layer 30 suitably has a thickness of 10 μm or more.

The resin layer 30 is bonded onto the sheet of metal foil 31. The sheet of metal foil 31 may specifically be, but does not have to be, a sheet of copper foil. The sheet of metal foil 31 may be patterned into conductor wiring by having unnecessary portions thereof etched away by a subtractive process, for example.

The thickness of the sheet of metal foil 31 is not limited to any particular value but is suitably 35 μm or less, and more suitably 18 μm or less. The sheet of metal foil 31 suitably has a thickness of 5 μm or more.

Optionally, the sheet of metal foil 31 may be configured as an extremely thin sheet of metal foil (such as an extremely thin sheet of copper foil) of a so-called “extremely thin sheet of metal foil with a carrier.” The extremely thin sheet of metal foil with the carrier has a triple layer structure. That is to say, the extremely thin sheet of metal foil with the carrier includes: the carrier; a peelable layer provided on the surface of the carrier; and an extremely thin sheet of metal foil provided on the surface of the peelable layer. The extremely thin sheet of metal foil is too thin to be handled easily by itself and is naturally thinner than the carrier. The carrier is a sheet of metal foil (such as a sheet of copper foil) that plays the role of supporting the extremely thin sheet of metal foil. The extremely thin sheet of metal foil with the carrier is relatively thick and thick enough to handle easily. The thicknesses of the extremely thin sheet of metal foil and the carrier are not limited to any particular values. For example, the extremely thin sheet of metal foil may have a thickness falling within the range from 1 μm to 10 μm, for example, and the carrier may have a thickness falling within the range from 18 μm to 35 μm. The extremely thin sheet of metal foil may be peeled off as needed from the carrier.

When the extremely thin sheet of metal foil with the carrier is used, the sheet of metal foil with resin 3 may be manufactured in the following manner. Specifically, the resin composition is applied onto the surface of the extremely thin sheet of metal foil of the extremely thin sheet of metal foil with the carrier and heated to form a resin layer 30. Thereafter, the carrier is peeled off from the extremely thin sheet of metal foil. The extremely thin sheet of metal foil is bonded as a sheet of metal foil 31 on the surface of the resin layer 30. The peelable layer is suitably peeled off along with the carrier and should not be left on the surface of the extremely thin sheet of metal foil. Nevertheless, even if any part of the peelable layer remains on the surface of the extremely thin sheet of metal foil, the remaining part of the peelable layer is easily removable. The extremely thin sheet of metal foil bonded on the surface of the resin layer 30 may be used as a seed layer in a modified semi-additive process (MSAP). The conductor wiring may be formed by subjecting the seed layer to an electrolytic plating process.

The resin layer 30 of the sheet of metal foil with resin 3 is made of the resin composition according to this embodiment, thus allowing a board having a low coefficient of thermal expansion, a high glass transition temperature (Tg), and excellent desmear resistance to be obtained.

(2.5) Metal-Clad Laminate

FIG. 4 illustrates a metal-clad laminate 4 according to this embodiment. The metal-clad laminate 4 includes an insulating layer 40 and a metal layer 41. The metal-clad laminate 4 may be used, for example, as a material for the printed wiring board 5.

The insulating layer 40 is made of either a cured product of the resin composition or a cured product of the prepreg 1. Although the insulating layer 40 includes a single base member 42 in the example illustrated in FIG. 4, the insulating layer 40 may include two or more base members 42.

The thickness of the insulating layer 40 is not limited to any particular value. The smaller the thickness of the insulating layer 40 is, the more effectively the insulating layer 40 contributes to reducing the thickness of the board. The thickness of the insulating layer 40 is suitably 120 μm or less, more suitably 100 μm or less, even more suitably 60 μm or less, and most suitably 40 μm or less. The insulating layer 40 suitably has a thickness of 10 μm or more, and more suitably has a thickness of 15 μm or more.

The metal layer 41 is formed on one surface or both surfaces of the insulating layer 40. The metal layer 41 may be, but does not have to be, a sheet of metal foil, for example. The sheet of metal foil may be, but does not have to be, a sheet of copper foil, for example. Although the metal layers 41 are provided on both surfaces of the insulating layer 40 in the example illustrated in FIG. 4, the metal layer 41 may be formed on only one surface of the insulating layer 40. The metal-clad laminate 4 including the metal layers 41 on both surfaces of the insulating layer 40 is a double-sided metal-clad laminate. The metal-clad laminate 4 including the metal layer 41 on only side of the insulating layer 40 is a single-sided metal-clad laminate.

The thickness of the metal layer 41 is not limited to any particular value but is suitably 35 μm or less and more suitably 18 μm or less. The metal layer 41 suitably has a thickness of 5 μm.

Optionally, the metal layer 41 may be formed out of the extremely thin sheet of metal foil of the extremely thin sheet of metal foil with the carrier. When the extremely thin sheet of metal foil with the carrier is used, the metal-clad laminate 4 may be manufactured in the following manner. Specifically, the extremely thin sheet of metal foil with the carrier may be stacked and formed on one surface or both surfaces of a single prepreg 1. Alternatively, a plurality of prepregs 1 may be stacked one on top of another and the extremely thin sheet of metal foil with the carrier may be stacked and formed on one surface or both surfaces of the stack of the plurality of prepregs 1. In that case, the extremely thin sheet of metal foil of the extremely thin sheet of metal foil with the carrier is stacked on the surface of the prepreg 1. After the stack has been formed, the carrier is peeled off from the extremely thin sheet of metal foil. The extremely thin sheet of metal foil is bonded as the metal layer 41 to the surface of the insulating layer 40, which is a cured product of the prepreg 1. The peelable layer is suitably peeled off along with the carrier and should not be left on the surface of the extremely thin sheet of metal foil. Nevertheless, even if any part of the peelable layer remains on the surface of the extremely thin sheet of metal foil, the remaining part of the peelable layer is easily removable. The extremely thin sheet of metal foil bonded on the surface of the insulating layer 40 may be used as a seed layer in a modified semi-additive process (MSAP). The conductor wiring may be formed by subjecting the seed layer to an electrolytic plating process.

The insulating layer 40 of the metal-clad laminate 4 is formed of the resin composition according to this embodiment, thus allowing a board having a low coefficient of thermal expansion, a high glass transition temperature (Tg), and excellent desmear resistance to be obtained. The coefficient of thermal expansion is suitably 10 ppm/K or less. The glass transition temperature (Tg) is suitably 250° C. or more and more suitably 260° C. or more.

(2.6) Printed Wiring Board

FIG. 5 illustrates a printed wiring board 5 according to this embodiment. The printed wiring board 5 includes an insulating layer 50 and conductor wiring 51. As used herein, the “printed wiring board” refers to a board to which no electronic components have been soldered yet and which includes only the wiring thereon.

The insulating layer 50 is made of either a cured product of the resin composition or a cured product of the prepreg 1. The insulating layer 50 may be the same as the insulating layer 40 of the metal-clad laminate 4.

The conductor wiring 51 is formed on one surface or both surfaces of the insulating layer 50. In FIG. 5, the conductor wiring 51 is formed on each of the two surfaces of the insulating layer 50. However, this is only an example and should not be construed as limiting. Alternatively, the conductor wiring 51 may be provided on only one surface of the insulating layer 50. The conductor wiring 51 may be formed by any method without limitation. Examples of methods for forming the conductor wiring 51 include a subtractive process, a semi-additive process (SAP), and a modified semi-additive process (SAP).

The insulating layer 50 of the printed wiring board 5 is made of the resin composition according to this embodiment, thus allowing a board having a low coefficient of thermal expansion, a high glass transition temperature (Tg), and excellent desmear resistance to be obtained. Thus, using the printed wiring board 5 as a package board would effectively contribute to reducing the warpage of a semiconductor package.

(3) Resume

As can be seen from the foregoing description of embodiments, the present disclosure has the following aspects. In the following description, reference signs are inserted in parentheses just for the sake of clarifying correspondence in constituent elements between the following aspects of the present disclosure and the exemplary embodiments described above.

A resin composition according to a first aspect contains an epoxy compound, a maleimide compound, a phenolic compound, core-shell rubber, and an inorganic filler. The maleimide compound has an N-phenyl maleimide structure. The content of the maleimide compound falls within a range from 10 parts by mass to less than 40 parts by mass with respect to 100 parts by mass in total of the epoxy compound, the maleimide compound, and the phenolic compound.

This aspect allows a board having a low coefficient of thermal expansion, a high glass transition temperature (Tg), and excellent desmear resistance to be obtained.

In a resin composition according to a second aspect, which may be implemented in conjunction with the first aspect, the maleimide compound includes a maleimide compound further having a biphenyl structure.

This aspect allows, even if the resin composition is filled with an inorganic filler at a high percentage, excellent flowability to be maintained during melting. In addition, this aspect also allows a resin composition with excellent flame retardance and other beneficial properties to be obtained.

In a resin composition according to a third aspect, which may be implemented in conjunction with the second aspect, the maleimide compound includes a compound expressed by the following Chemical Formula (1):

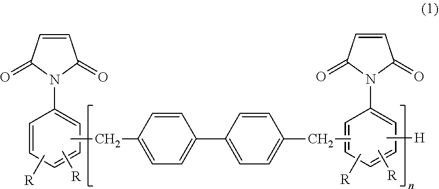

where R represents groups which are either the same as, or different from, each other, and each of which is either a hydrogen atom or an alkyl group; and n is an integer falling within a range from 0 to 4.

This aspect allows, even if the resin composition is filled with an inorganic filler at a high percentage, excellent flowability to be maintained during melting. In addition, this aspect also allows a resin composition with excellent flame retardance and other beneficial properties to be obtained.

In a resin composition according to a fourth aspect, which may be implemented in conjunction with the first aspect, the maleimide compound includes a compound expressed by the following Chemical Formula (2):

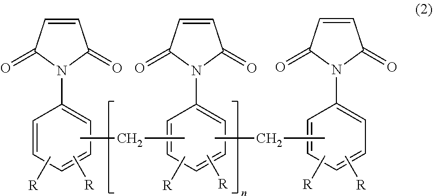

where R represents groups which are either the same as, or different from, each other, and each of which is either a hydrogen atom or an alkyl group; and n is an integer falling within a range from 0 to 4.

This aspect allows a cured product of the resin composition to have a high Tg, thus improving the thermal resistance.

In a resin composition according to a fifth aspect, which may be implemented in conjunction with any one of the first to fourth aspects, the epoxy compound includes an epoxy compound having at least one of a naphthalene skeleton or a biphenyl skeleton.

This aspect allows, when the resin composition includes an epoxy compound having a naphthalene skeleton, a resin composition having excellent thermal resistance, moisture resistance, and flame retardance to be obtained. In addition, this aspect also allows, when the resin composition includes an epoxy compound having a biphenyl skeleton, excellent flowability to be maintained during melting even if the resin composition is filled with an inorganic filler at a high percentage. Furthermore, this aspect also allows a resin composition with excellent flame retardance and other beneficial properties to be obtained.

In a resin composition according to a sixth aspect, which may be implemented in conjunction with any one of the first to fifth aspects, the phenolic compound includes a phenolic compound having at least one of a naphthalene skeleton or a biphenyl skeleton.

This aspect allows, when the resin composition includes a phenolic compound having a naphthalene skeleton, a resin composition having excellent thermal resistance, moisture resistance, and flame retardance to be obtained. In addition, this aspect also allows, when the resin composition includes a phenolic compound having a biphenyl skeleton, excellent flowability to be maintained during melting even if the resin composition is filled with an inorganic filler at a high percentage. Furthermore, this aspect also allows a resin composition with excellent flame retardance and other beneficial properties to be obtained.

In a resin composition according to a seventh aspect, which may be implemented in conjunction with any one of the first to sixth aspects, content of the phenolic compound falls within a range from 10 parts by mass to 30 parts by mass with respect to 100 parts by mass in total of the epoxy compound, the maleimide compound, and the phenolic compound.

According to this aspect, setting the content of the phenolic compound at 10 parts by mass or more allows a decline in glass transition temperature (Tg) and a decline in desmear resistance to be curbed. In addition, setting the content of the phenolic compound at 30 parts by mass or less allows a decline in desmear resistance to be curbed.

In a resin composition according to an eighth aspect, which may be implemented in conjunction with any one of the first to seventh aspects, the core-shell rubber includes a core and a shell that covers the core. The core includes one or more substances selected from the group consisting of a polymer of (meth)acrylic acid, a polymer of a (meth)acrylate ester, a polymer of an olefin compound, polybutadiene, and silicone. The shell includes one or more substances selected from the group consisting of a styrene-acrylonitrile copolymer, a polymer of (meth)acrylic acid, polybutadiene, and silicone.

This aspect may impart thermal resistance and low-temperature shock resistance to a cured product of the resin composition.

In a resin composition according to a ninth aspect, which may be implemented in conjunction with any one of the first to eighth aspects, the core-shell rubber has a mean particle size less than 1 μm.

This aspect allows, when an insulating layer is formed out of a resin composition on a surface with conductor wiring of a printed wiring board, the gap between adjacent portions of the conductor wiring to be filled more easily. This aspect is applicable particularly effectively to a printed wiring board on which a fine-line conductor wiring pattern (i.e., a so-called “fine pattern”) has been formed at a high density.

In a resin composition according to a tenth aspect, which may be implemented in conjunction with any one of the first to ninth aspects, the inorganic filler includes one or more compounds selected from the group consisting of silica, talc, boehmite, magnesium hydroxide, and aluminum hydroxide.

This aspect contributes particularly effectively to reducing the thermal expansion of a cured product of the resin composition to a sufficiently low level.

A prepreg (1) according to an eleventh aspect includes: a base member (11): and a resin layer (10) made of a semi-cured product of the resin composition according to any one of the first to tenth aspects. The semi-cured product is impregnated into the base member (11).

This aspect allows a board having a low coefficient of thermal expansion, a high glass transition temperature (Tg), and excellent desmear resistance to be obtained.

A film with resin (2) according to a twelfth aspect includes: a resin layer (20) made of a semi-cured product of the resin composition according to any one of the first to tenth aspects; and a supporting film (21) supporting the resin layer (20) thereon.

This aspect allows a board having a low coefficient of thermal expansion, a high glass transition temperature (Tg), and excellent desmear resistance to be obtained.

A sheet of metal foil with resin (3) according to a thirteenth aspect includes: a resin layer (30) made of a semi-cured product of the resin composition according to any one of the first to tenth aspects; and a sheet of metal foil (31) to which the resin layer (30) is bonded.

This aspect allows a board having a low coefficient of thermal expansion, a high glass transition temperature (Tg), and excellent desmear resistance to be obtained.

A metal-clad laminate (4) according to a fourteenth aspect includes: an insulating layer (40) made of either a cured product of the resin composition according to any one of the first to tenth aspects or a cured product of the prepreg (1) according to the eleventh aspect; and at least one metal layer (41) formed on one surface or both surfaces of the insulating layer (40).

This aspect allows a board having a low coefficient of thermal expansion, a high glass transition temperature (Tg), and excellent desmear resistance to be obtained.

A printed wiring board (5) according to a fifteenth aspect includes: an insulating layer (50) made of either a cured product of the resin composition according to any one of the first to tenth aspects or a cured product of the prepreg (1) according to the eleventh aspect; and at least one conductor wiring (51) formed on one surface or both surfaces of the insulating layer (50).

This aspect allows a board having a low coefficient of thermal expansion, a high glass transition temperature (Tg), and excellent desmear resistance to be obtained.

### Examples

Next, the present disclosure will be described specifically by way of illustrative examples. Note that the following are only examples of the present disclosure and should not be construed as limiting.

(1) Resin Composition

The following materials were provided as materials for a resin composition. Then, the epoxy compound, the phenolic compound, the maleimide compound, the core-shell rubber, the inorganic filler, and the curing accelerator were compounded together to have any of the compositions shown in the following Tables 1-3. Each of those compounds was diluted with a solvent (such as methyl ethyl ketone) and then stirred up and mixed to have a uniform concentration. In this manner, the resin composition was prepared.

(1.1) Epoxy Compound
Biphenyl aralkyl type epoxy resin (product name “NC-3500” manufactured by Nippon Kayaku Co., Ltd. and having an epoxy equivalent of 209 g/eq),
Naphthalene type epoxy resin (product name “HP-9500” manufactured by DIC Corporation and having an epoxy equivalent of 230 g/eq),
Triphenylmethane skeleton-containing epoxy resin (product name “EPPN-502H” manufactured by Nippon Kayaku Co., Ltd. and having an epoxy equivalent of 158-178 g/eq),
Naphthalene type epoxy resin (product name “HP-4710” manufactured by DIC Corporation and having an epoxy equivalent of 170 g/eq), and
Biphenyl aralkyl type epoxy resin (product name “NC-3000-H” manufactured by Nippon Kayaku Co., Ltd. and having an epoxy equivalent of 280-300 g/eq).

(1.2) Phenolic Compound
Naphthalene type phenolic resin (product name “HPC9500P-53M” manufactured by DIC Corporation and having a hydroxyl equivalent of 153 g/eq),
Biphenyl aralkyl type phenolic resin (product name “MEHC-7403H” manufactured by Meiwa Kasei Industries, Ltd. and having a hydroxyl equivalent of 132 g/eq), and
Phosphorus-containing phenolic compound (product name “XZ92741.00” manufactured by the Dow Chemical Company Japan and having a hydroxyl equivalent of 550 g/eq).

(1.3) Maleimide Compound
Phenyl methane maleimide (product name “BMI-2300” manufactured by Daiwa Chemical Industry Co., Ltd.), and
Biphenyl aralkyl type maleimide resin (product name “MIR-3000 70MT” manufactured by Nippon Kayaku Co., Ltd.).

(1.4) Core-Shell Rubber
Methyl methacrylate butadiene styrene core-shell rubber (product name “TMS-2670J” manufactured by the Dow Chemical Company Japan; core: methyl methacrylate/butadiene/styrene copolymer; shell: methyl methacrylate polymer; having a mean particle size of 0.151 μm),
Acrylic rubber (product name “AC3816N” manufactured by Aica Kogyo Co., Ltd.; core: crosslinked acrylic polymer; shell: methyl methacrylate polymer; having a mean particle size of 0.3 μm), and
Silicone-acrylic composite rubber (product name “SRK200A” manufactured by Mitsubishi Chemical Corporation; core: silicone/acrylic polymer; shell: styrene acrylonitrile copolymer; having a mean particle size of 0.15 μm).

(1.5) Inorganic Filler
Silica (product name “SC-2050MTX” manufactured by Admatechs and having a mean particle size of 0.5 μm),
Silica (product name “SC-2050MNU” manufactured by Admatechs and having a mean particle size of 0.5 μm),
Aluminum hydroxide (product name “ALH-F” manufactured by Kawai Lime Industry Co., Ltd. and having a mean particle size of 5.2 μm), and
Magnesium hydroxide (product name “KISUMA 8SN” manufactured by Kyowa Chemical Industry Co., Ltd. and having a mean particle size of 1.48 μm).

(1.6) Curing Accelerator
2-ethyl-4-methylimidazole (product name “2E4MZ” manufactured by Shikoku Chemicals Corporation).

(2) Prepreg

A piece of glass cloth (#2118 type, WEA 2118T-107-S199, E glass manufactured by Nitto Boseki Co., Ltd.) was provided. The piece of glass cloth was a piece of woven fabric, of which the warp and woof were woven substantially orthogonally to each other. This piece of glass cloth was impregnated with the resin composition such that a cured product of the prepreg would have a thickness of 100 μm. Next, the resin composition impregnated into the piece of glass cloth was heated and dried by a contactless type heating unit until the resin composition was semi-cured. The heating temperature was in the range of 120° C. to 130° C. In this manner, the solvent was removed from the resin composition, thereby manufacturing a prepreg including the piece of glass cloth and the semi-cured product of the resin composition impregnated into the piece of glass cloth. The resin content (i.e., the content of resin) of the prepreg was 41 parts by mass with respect to 100 parts by mass of the prepreg.

(3) Metal-Clad Laminate

Two prepregs, each having the structure described above, were laid one on top of the other to obtain a stack of prepregs. A sheet of copper foil (with a thickness of 12 μm) was laminated onto each of the two surfaces of the stack thus obtained, thereby forming a stack of prepregs with sheets of copper foil. Then, the stack of prepregs with sheets of copper foil was formed under heat and pressure to make a double-sided metal-clad laminate with a thickness of 0.2 mm. The forming process under heat and pressure was carried out under the condition including 220° C., 2 MPa, and 90 minutes.

(4) Test

(4.1) Coefficient of Thermal Expansion (CTE)

The sheets of copper foil that had been bonded to both surfaces of the double-sided metal-clad laminate were etched away to obtain an unclad plate. Using this unclad plate as a sample, the coefficient of thermal expansion (CTE) was measured perpendicularly to the thickness direction within a temperature range of 50° C. to 260° C. The measurement was carried out by thermal mechanical analysis (TMA) method compliant with the IPC TM650 2.4.41 standard.

(4.2) Glass Transition Temperature (Tg)

The sheets of copper foil that had been bonded to both surfaces of the double-sided metal-clad laminate were etched away to obtain an unclad plate. The unclad plate was cut out in a biasing direction forming a tilt angle of 45 degrees with respect to the warp and woof of the piece of glass cloth, thereby obtaining a sample with dimensions of 50 mm×5 mm.

This sample had its tan δ measured at a temperature increase rate of 5° C./min (by dynamic mechanical analysis (DMA)) using a dynamic mechanical spectrometer (“DMS6100” manufactured by SII Nanotechnology Inc.). A peak temperature thereof was regarded as a glass transition temperature (Tg).

(4.3) Desmear Resistance

The desmear resistance was evaluated by a desmear etch rate, which was calculated as the difference between the mass of the following unprocessed test piece yet to be subjected to the desmear process and the mass of the following processed test piece that had been subjected to the desmear process using a permanganate.

Specifically, the sheets of copper foil that had been bonded to a double-sided metal-clad laminate having dimensions of 5 cm×5 cm were etched away to obtain a test piece. Then, the desmear etch rate (of which the unit is mg/cm²) was calculated based on the difference between the mass (initial mass) of the unprocessed test piece yet to be subjected to the desmear process and the mass of the processed test piece that had been subjected to the desmear process under the following condition.

The initial mass of the unprocessed test piece was measured after the test piece had been dried at 130° C. for 30 minutes and then air-cooled for two hours in a desiccator.

The mass of the processed test piece was measured in the following manner.

(a) Swelling Process

First, after having its initial mass measured, the unprocessed test piece was allowed to swell for 5 minutes in “Swelling Dip Securiganth P (500 ml/L)” manufactured by Atotech Japan and an aqueous solution of sodium hydroxide (40 g/L).

(b) Desmear Process

Next, the test piece was subjected to a micro-etching process for 10 minutes with “Concentrate Compact CP (580 ml/L)” manufactured by Atotech Japan and an aqueous solution of sodium hydroxide (40 g/L).

(c) Neutralization Process

Next, the test piece was neutralized for 5 minutes with “Reduction Solution Securiganth P500 (70 ml/L)” manufactured by Atotech Japan and sulfuric acid (98%, 50 ml/L).

(d) Drying Process

Next, the test piece was dried for 30 minutes at 130° C.

Then, the desmear resistance was evaluated separately in 1 pass and 2 pass as follows.

In the 1 pass, after the test piece had gone through the series of processes (a) through (d) once, the test piece was air-cooled for 2 hours, and then the mass of the processed test piece was measured. In this manner, the desmear etch rate of the 1 pass was measured.

In the 2 pass, after the test piece had gone through the series of processes (a) through (c) twice and gone through the process (d), the test piece was air-cooled for 2 hours, and then the mass of the processed test piece was measured. In this manner, the desmear etch rate of the 2 pass was measured.

The desmear resistance was rated excellent when the desmear etch rate was 0.3 mg/cm² or less in the 1 pass and 0.5 mg/cm² or less in the 2 pass.

TABLE 1

| | | | Examples | | | | | | | |
|---|---|---|---|---|---|---|---|---|---|---|
| | | | 1 | 2 | 3 | 4 | 5 | 6 | 7 | 8 |
| Epoxy | NC-3500 | parts by | 45 | 40 | 35 | 55 | 20 | 21 | 0 | 35 |
| compound | | mass | | | | | | | | |
| | HP-9500 | parts by | 0 | 0 | 0 | 0 | 0 | 0 | 20 | 0 |
| | | mass | | | | | | | | |
| | EPPN-502H | parts by | 0 | 0 | 0 | 0 | 0 | 0 | 0 | 0 |
| | | mass | | | | | | | | |
| | HP-4710 | parts by | 0 | 0 | 0 | 0 | 0 | 0 | 0 | 0 |
| | | mass | | | | | | | | |
| | NC-3000-H | parts by | 0 | 0 | 0 | 0 | 20 | 24 | 20 | 0 |
| | | mass | | | | | | | | |
| Phenolic | HPC9500P-53M | parts by | 13.9 | 18.9 | 23.9 | 28.9 | 0 | 0 | 0 | 30 |
| compound | | mass | | | | | | | | |
| | MEHC-7403H | parts by | 0 | 0 | 0 | 0 | 18.9 | 13.9 | 18.9 | 0 |
| | | mass | | | | | | | | |
| | XZ92741.00 | parts by | 6.1 | 6.1 | 6.1 | 6.1 | 6.1 | 6.1 | 6.1 | 0 |
| | | mass | | | | | | | | |
| Maleimide | BMI2300 | parts by | 35 | 35 | 35 | 10 | 0 | 0 | 35 | 35 |
| compound | | mass | | | | | | | | |
| | MIR-3000 70MT | parts by | 0 | 0 | 0 | 0 | 35 | 35 | 0 | 0 |
| | | mass | | | | | | | | |
| Core-shell | TMS-2670J | parts by | 0 | 0 | 0 | 0 | 0 | 0 | 0 | 0 |
| rubber | | mass | | | | | | | | |
| | AC3816N | parts by | 0 | 0 | 0 | 0 | 0 | 0 | 0 | 0 |
| | | mass | | | | | | | | |
| | SRK200A | parts by | 21.4 | 21.4 | 21.4 | 21.4 | 21.4 | 21.4 | 21.4 | 21.4 |
| | | mass | | | | | | | | |
| Inorganic | SC-2050MTX | parts by | 82.9 | 82.9 | 82.9 | 82.9 | 82.9 | 82.9 | 82.9 | 82.9 |
| filler | | mass | | | | | | | | |
| | SC-2050MNU | parts by | 0 | 0 | 0 | 0 | 0 | 0 | 0 | 0 |
| | | mass | | | | | | | | |
| | ALH-F | parts by | 0 | 0 | 0 | 0 | 0 | 0 | 0 | 0 |
| | | mass | | | | | | | | |
| | KISUMA 8SN | parts by | 3.1 | 3.1 | 3.1 | 3.1 | 3.1 | 3.1 | 3.1 | 3.1 |
| | | mass | | | | | | | | |
| Curing | 2E4MZ | phr | 0.075 | 0.075 | 0.075 | 0.075 | 0.15 | 0.15 | 0.10 | 0.075 |
| accelerator | | | | | | | | | | |
| Test items | Coefficient of | ppm/K | 8.2 | 7.5 | 7.6 | 8.4 | 7.6 | 7.9 | 7.7 | 8.2 |
| | thermal expansion | | | | | | | | | |
| | (CTE) | | | | | | | | | |
| | Glass transition | ° C. | 260 | 266 | 265 | 259 | 264 | 262 | 262 | 271 |
| | temperature (Tg) | | | | | | | | | |
| | Desmear | mg/cm² | 0.14 | 0.20 | 0.24 | 0.06 | 0.06 | 0.04 | 0.10 | 0.24 |
| | resistance | | | | | | | | | |
| | (1 pass) | | | | | | | | | |
| | Desmear | mg/cm² | 0.29 | 0.34 | 0.48 | 0.16 | 0.16 | 0.10 | 0.20 | 0.49 |
| | resistance | | | | | | | | | |
| | (2 pass) | | | | | | | | | |

TABLE 2

| | | | Examples | | | | | | | | | | |
|---|---|---|---|---|---|---|---|---|---|---|---|---|---|
| | | | 9 | 10 | 11 | 12 | 13 | 14 | 15 | 16 | 17 | 18 | 19 |
| Epoxy | NC-3500 | parts by | 40 | 40 | 20 | 44 | 48 | 24 | 24 | 24 | 36 | 36 | 36 |
| compound | | mass | | | | | | | | | | | |
| | HP-9500 | parts by | 0 | 0 | 0 | 0 | 0 | 24 | 0 | 0 | 0 | 12 | 0 |
| | | mass | | | | | | | | | | | |
| | EPPN-502H | parts by | 0 | 0 | 0 | 0 | 0 | 0 | 24 | 0 | 0 | 0 | 12 |
| | | mass | | | | | | | | | | | |
| | HP-4710 | parts by | 0 | 0 | 0 | 0 | 0 | 0 | 0 | 24 | 0 | 0 | 0 |
| | | mass | | | | | | | | | | | |
| | NC-3000-H | parts by | 0 | 0 | 20 | 0 | 0 | 0 | 0 | 0 | 12 | 0 | 0 |
| | | mass | | | | | | | | | | | |
| Phenolic | HPC9500P-53M | parts by | 0 | 0 | 0 | 20.2 | 21.2 | 21.2 | 21.2 | 21.2 | 21.2 | 21.2 | 21.2 |
| compound | | mass | | | | | | | | | | | |
| | MEHC-7403H | parts by | 18.9 | 18.9 | 18.9 | 0 | 0 | 0 | 0 | 0 | 0 | 0 | 0 |
| | | mass | | | | | | | | | | | |
| | XZ92741.00 | parts by | 6.1 | 6.1 | 6.1 | 5.8 | 5.8 | 5.8 | 5.8 | 5.8 | 5.8 | 5.8 | 5.8 |
| | | mass | | | | | | | | | | | |
| Maleimide | BMI2300 | parts by | 35 | 35 | 35 | 0 | 0 | 0 | 0 | 0 | 0 | 0 | 0 |
| compound | | mass | | | | | | | | | | | |
| | MIR-3000 70MT | parts by | 0 | 0 | 0 | 30 | 25 | 25 | 25 | 25 | 25 | 25 | 25 |
| | | mass | | | | | | | | | | | |
| Core-shell | TMS-2670J | parts by | 39.7 | 0 | 39.7 | 0 | 0 | 0 | 0 | 0 | 0 | 0 | 0 |
| rubber | | mass | | | | | | | | | | | |
| | AC3816N | parts by | 0 | 39.7 | 0 | 0 | 0 | 0 | 0 | 0 | 0 | 0 | 0 |
| | | mass | | | | | | | | | | | |
| | SRK200A | parts by | 0 | 0 | 0 | 39.7 | 39.7 | 39.7 | 39.7 | 39.7 | 39.7 | 39.7 | 39.7 |
| | | mass | | | | | | | | | | | |
| Inorganic | SC-2050MTX | parts by | 0 | 0 | 0 | 0 | 0 | 0 | 0 | 0 | 0 | 0 | 0 |
| filler | | mass | | | | | | | | | | | |
| | SC-2050MNU | parts by | 98.3 | 98.3 | 98.3 | 98.3 | 98.3 | 98.3 | 98.3 | 98.3 | 98.3 | 98.3 | 98.3 |
| | | mass | | | | | | | | | | | |
| | ALH-F | parts by | 3.1 | 3.1 | 3.1 | 3.1 | 3.1 | 3.1 | 3.1 | 3.1 | 3.1 | 3.1 | 3.1 |
| | | mass | | | | | | | | | | | |
| | KISUMA 8SN | parts by | 0 | 0 | 0 | 3.1 | 3.1 | 3.1 | 3.1 | 3.1 | 3.1 | 3.1 | 3.1 |
| | | mass | | | | | | | | | | | |
| Curing | 2E4MZ | phr | 0.15 | 0.15 | 0.15 | 0.075 | 0.075 | 0.075 | 0.075 | 0.075 | 0.075 | 0.075 | 0.075 |
| accelerater | | | | | | | | | | | | | |
| Test items | Coefficient of | ppm/K | 8.4 | 8.8 | 8.7 | 7.8 | 7.9 | 8.1 | 7.8 | 8.1 | 7.8 | 7.6 | 7.7 |
| | thermal expansion | | | | | | | | | | | | |
| | (CTE) | | | | | | | | | | | | |
| | Glass transition | ° C. | 261 | 263 | 255 | 264 | 262 | 257 | 258 | 262 | 259 | 259 | 260 |
| | temperature (Tg) | | | | | | | | | | | | |
| | Desmear | mg/cm² | 0.22 | 0.21 | 0.30 | 0.18 | 0.17 | 0.18 | 0.24 | 0.29 | 0.17 | 0.18 | 0.20 |
| | resistance | | | | | | | | | | | | |
| | (1 pass) | | | | | | | | | | | | |
| | Desmear | mg/cm² | 0.35 | 0.33 | 0.32 | 0.29 | 0.28 | 0.27 | 0.32 | 0.48 | 0.28 | 0.29 | 0.29 |
| | resistance | | | | | | | | | | | | |
| | (2 pass) | | | | | | | | | | | | |

TABLE 3

| | | | Comparative Examples | | | |
|---|---|---|---|---|---|---|
| | | | 1 | 2 | 3 | 4 |
| Epoxy | NC-3500 | parts by | 65 | 61.5 | 30 | 40 |
| compound | | mass | | | | |
| | HP-9500 | parts by | 0 | 0 | 0 | 0 |
| | | mass | | | | |
| | EPPN-502H | parts by | 0 | 0 | 0 | 0 |
| | | mass | | | | |
| | HP-4710 | parts by | 0 | 0 | 0 | 0 |
| | | mass | | | | |
| | NC-3000-H | parts by | 0 | 0 | 0 | 0 |
| | | mass | | | | |
| Phenolic | HPC9500P-53M | parts by | 0 | 32.4 | 23.9 | 20 |
| compound | | mass | | | | |
| | MEHC-7403H | parts by | 0 | 0 | 0 | 0 |
| | | mass | | | | |
| | XZ92741.00 | parts by | 0 | 6.1 | 6.1 | 5 |
| | | mass | | | | |
| Maleimide | BMI2300 | parts by | 35 | 0 | 40 | 35 |
| compound | | mass | | | | |
| | MIR-3000 70MT | parts by | 0 | 0 | 0 | 0 |
| | | mass | | | | |
| Core-shell | TMS-2670J | parts by | 0 | 0 | 0 | 0 |
| rubber | | mass | | | | |
| | AC3816N | parts by | 0 | 0 | 0 | 0 |
| | | mass | | | | |
| | SRK200A | parts by | 21.4 | 21.4 | 21.4 | 0 |
| | | mass | | | | |
| Inorganic | SC-2050MTX | parts by | 82.9 | 82.9 | 82.9 | 82.9 |
| filler | | mass | | | | |
| | SC-2050MNU | parts by | 0 | 0 | 0 | 0 |
| | | mass | | | | |
| | ALH-F | parts by | 0 | 0 | 0 | 0 |
| | | mass | | | | |
| | KISUMA 8SN | parts by | 3.1 | 3.1 | 0 | 3.1 |
| | | mass | | | | |
| Curing | 2E4MZ | phr | 0.075 | 0.075 | 0.075 | 0.075 |
| accelerator | | | | | | |
| Test items | Coefficient of | ppm/K | 7.8 | 8.3 | 8.0 | 11.1 |
| | thermal expansion | | | | | |
| | (CTE) | | | | | |
| | Glass transition | ° C. | 175 | 234 | 260 | 271 |
| | temperature (Tg) | | | | | |
| | Desmear | mg/cm² | 0.68 | 0.04 | 0.31 | 0.15 |
| | resistance | | | | | |
| | (1 pass) | | | | | |
| | Desmear | mg/cm² | 1.58 | 0.12 | 0.61 | 0.31 |
| | resistance | | | | | |
| | (2 pass) | | | | | |

### REFERENCE SIGNS LIST

1 Prepreg
2 Resin Layer
11 Base Member
2 Film with Resin
20 Resin Layer
21 Supporting Film
3 Sheet of Metal Foil with Resin
30 Resin Layer
31 Sheet of Metal Foil
4 Metal-Clad Laminate
40 Insulating Layer
41 Metal Layer
5 Printed Wiring Board
50 Insulating Layer
51 Conductor Wiring

1. A resin composition comprising: an epoxy compound; a maleimide compound having an N-phenyl maleimide structure; a phenolic compound; core-shell rubber; and an inorganic filler,
content of the maleimide compound falling within a range from 10 parts by mass to less than 40 parts by mass with respect to 100 parts by mass in total of the epoxy compound, the maleimide compound, and the phenolic compound.

2. The resin composition of claim 1, wherein
the maleimide compound includes a maleimide compound further having a biphenyl structure.

3. The resin composition of claim 2, wherein
the maleimide compound includes a compound expressed by the following Chemical Formula (1): 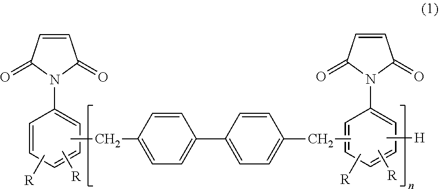
where R represents groups which are either the same as, or different from, each other, and each of which is either a hydrogen atom or an alkyl group; and n is an integer falling within a range from 0 to 4.

4. The resin composition of claim 1, wherein
the maleimide compound includes a compound expressed by the following Chemical Formula (2): 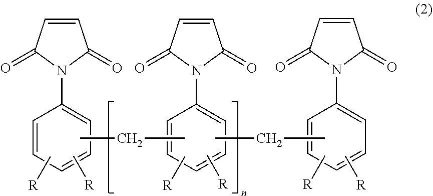
where R represents groups which are either the same as, or different from, each other, and each of which is either a hydrogen atom or an alkyl group; and n is an integer falling within a range from 0 to 4.

5. The resin composition of claim 1, wherein
the epoxy compound includes an epoxy compound having at least one of a naphthalene skeleton or a biphenyl skeleton.

6. The resin composition of claim 1, wherein
the phenolic compound includes a phenolic compound having at least one of a naphthalene skeleton or a biphenyl skeleton.

7. The resin composition of claim 1, wherein
content of the phenolic compound falls within a range from 10 parts by mass to 30 parts by mass with respect to 100 parts by mass in total of the epoxy compound, the maleimide compound, and the phenolic compound.

8. The resin composition of claim 1, wherein
the core-shell rubber includes a core and a shell that covers the core,
the core includes one or more substances selected from the group consisting of a polymer of (meth)acrylic acid, a polymer of a (meth)acrylate ester, a polymer of an olefin compound, polybutadiene, and silicone, and
the shell includes one or more substances selected from the group consisting of a styrene-acrylonitrile copolymer, a polymer of (meth)acrylic acid, polybutadiene, and silicone.

9. The resin composition of claim 1, wherein
the core-shell rubber has a mean particle size less than 1 μm.

10. The resin composition of claim 1, wherein
the inorganic filler includes one or more compounds selected from the group consisting of silica, talc, boehmite, magnesium hydroxide, and aluminum hydroxide.

11. A prepreg comprising: a base member: and a resin layer made of a semi-cured product of the resin composition according to claim 1, the semi-cured product being impregnated into the base member.

12. A film with resin comprising: a resin layer made of a semi-cured product of the resin composition according to claim 1; and a supporting film supporting the resin layer thereon.

13. A sheet of metal foil with resin, comprising: a resin layer made of a semi-cured product of the resin composition according to claim 1; and a sheet of metal foil to which the resin layer is bonded.

14. A metal-clad laminate comprising: an insulating layer made of either a cured product of the resin composition according to claim 1; and at least one metal layer formed on one surface or both surfaces of the insulating layer.

15. A printed wiring board comprising: an insulating layer made of either a cured product of the resin composition according to claim 1; and at least one conductor wiring formed on one surface or both surfaces of the insulating layer.
